(19) United States
(12) Patent Application Publication
(10) Pub. No.: US 2023/0193132 A1
(43) Pub. Date: Jun. 22, 2023

(54) ETCHING COMPOSITION FOR REMOVING SILICON AND METHOD FOR REMOVING SILICON BY USING THE SAME

(71) Applicant: LCY CHEMICAL CORP., Kaohsiung City (TW)

(72) Inventors: Shang-Chen HUANG, Kaohsiung City (TW); Cheng-Huan HSIEH, Kaohsiung City (TW)

(21) Appl. No.: 18/083,829

(22) Filed: Dec. 19, 2022

Related U.S. Application Data
(60) Provisional application No. 63/291,533, filed on Dec. 20, 2021.

(30) Foreign Application Priority Data
Nov. 7, 2022 (TW) 111142324

(51) Int. Cl. C09K 13/02; H01L 21/768

(52) U.S. Cl. CPC C09K 13/02; H01L 21/76813

(57) ABSTRACT

An etching composition for removing silicon is provided, which comprises: 1 to 5.5 wt % of a quaternary ammonium salt; 20 to 95.5 wt % of an alcohol amine compound; 1 to 40 wt % of an amide compound; and rest of water. In addition, a method for removing silicon using the aforesaid etching composition is also provided.

### CROSS-REFERENCE TO RELATED APPLICATIONS

This application claims the benefits of the Taiwan Patent Application Serial Number 111142324, filed on Nov. 7, 2022, the subject matter of which is incorporated herein by reference.

This application claims the benefit of filing date of U. S. Provisional Application Ser. No. 63/291,533, filed Dec. 20, 2021 under 35 USC § 119(e)(1).

### BACKGROUND OF THE INVENTION

### Field

The present disclosure provides an etching composition for removing silicon and a method for removing silicon by using the same. In particular, the present disclosure provides an etching composition with high etching selectivity of silicon relative to a silicon compound, a high work function material or a high-k material and a method for removing silicon by using the same.

### Description of Related Art

The wet etching process is one of the commonly used processes for preparing semiconductor devices, and some materials have to be selectively removed. For example, in the process for manufacturing a high-k metal gate transistor, an etching composition is used to remove a polysilicon gate, followed by replacing with a metal gate. Since other insulating materials (for example, silicon oxide, silicon nitride, silicon carbide or silicon carbide nitride) are formed around the polysilicon gate, high silicon etching selectivity has to be ensured during the etching process. If the silicon etching selectivity is poor, the surrounding insulating material may be lost or removed during the silicon removal process, resulting in defects in the obtained semiconductor device. Thus, the electrical performance of the obtained semiconductor device may be poor, or the manufacturing yield thereof may be reduced.

Therefore, it is desirable to provide an etching composition for removing silicon and a method for removing silicon by using the same, wherein the etching composition has excellent silicon etching selectivity and can be applied to the wet etching process of the semiconductor device.

### SUMMARY OF THE INVENTION

One object of the present disclosure is to provide an etching composition for removing silicon and a method for removing silicon by using the same. More specifically, the etching composition of the present disclosure has high etching selectivity of silicon relative to a silicon compound, a high work function material or a high-k material.

The etching composition for removing silicon of the present disclosure comprises: 1 to 5.5 wt % of a quaternary ammonium salt; 20 to 95.5 wt % of an alcohol amine compound; 1 to 40 wt % of an amide compound; and rest of water. More specifically, the etching composition of the present disclosure is an etching composition for removing amorphous silicon, monocrystalline silicon, polycrystalline silicon or a combination thereof.

In the present disclosure, by adding appropriate amount of the quaternary ammonium salt, the etching of silicon compounds (such as silicon dioxide, silicon nitride, silicon carbide or silicon carbide nitride), high work function materials (such as titanium nitride, tantalum nitride, ruthenium or molybdenum) or high-k materials (such as hafnium dioxide, titanium dioxide, or zirconium dioxide) can be inhibited or delayed, but good etching rate of silicon (such as amorphous silicon, monocrystalline silicon or polycrystalline silicon) can be exhibited.

In one embodiment, the quaternary ammonium salt may be represented by the following formula (I):

N(R¹)₄⁺X⁻ (I)

wherein each R¹ may independently be substituted or unsubstituted alkyl, or substituted or unsubstituted aryl; X⁻ may be F⁻, Cl⁻, Br⁻, I⁻, HSO₄⁻, R²COO⁻ or OH⁻; and R² may be H or substituted or unsubstituted alkyl.

In one embodiment, each R¹ may independently be substituted or unsubstituted alkyl, or substituted or unsubstituted aryl. In one embodiment, each R′ may independently be unsubstituted alkyl, aryl-substituted alkyl, hydroxyl-substituted alkyl, unsubstituted aryl or alkyl-substituted aryl. In one embodiment, each R¹ may independently be substituted or unsubstituted C₁₋₅ alkyl, or substituted or unsubstituted C₆₋₁₀ aryl. In one embodiment, each R¹ may independently be unsubstituted C₁₋₅ alkyl, C₆₋₁₀ aryl-substituted C₁₋₅ alkyl, hydroxyl-substituted C₁₋₅ alkyl, unsubstituted C₆₋₁₀ aryl or C₁₋₅ alkyl-substituted C₆₋₁₀ aryl. In one embodiment, each R¹ may independently be methyl, ethyl, propyl, butyl, hydroxyl-substituted methyl, hydroxyl-substituted ethyl, hydroxyl-substituted propyl, hydroxyl-substituted butyl, phenyl-substituted methyl, phenyl-substituted ethyl, phenyl-substituted propyl or phenyl-substituted butyl. Herein, each R¹ can be the same or different.

In one embodiment, X⁻ may be F⁻, Cl⁻, Br⁻, I⁻, HSO₄⁻, R²COO⁻, or OH⁻,and R² may be H or substituted or unsubstituted alkyl. In one embodiment, X⁻ may be F⁻, Cl⁻, Br⁻, I⁻, HSO₄⁻, R²COO⁻ or OH⁻, and R² may be H or substituted or unsubstituted C₁₋₅ alkyl. In one embodiment, X⁻may be F⁻, Cr⁻, Br⁻, I⁻, HSO₄⁻, R²COO⁻or OH⁻, and R² may be H. In one embodiment, X⁻may be OH⁻.

In one embodiment, specific examples of the quaternary ammonium salt may include, but are not limited to: tetramethyl ammonium hydroxide (TMAH), tetraethylammonium hydroxide (TEAH), tetrapropylammonium hydroxide (TPAH), tetrabutylammonium hydroxide (TBAH), benzyltrimethylammonium hydroxide, triethylmethylammonium hydroxide, choline hydroxide and a combination thereof. The aforesaid quaternary ammonium salts may be used alone or in combination of two or more.

In one embodiment, the content of the quaternary ammonium salt may be 1 to 5.5 wt %, for example, may be 1 to 5.25 wt %, 1 to 5 wt %, 1 to 4.75 wt %, 1 to 4.5 wt %, 1 to 4.25 wt %, 1 to 4 wt %, 1 to 3.75 wt %, 1 to 3.5 wt %, 1 to 3.25 wt %, 1 to 3 wt %, 1.25 to 3 wt %, 1.5 to 3 wt %, 1.75 to 3 wt %, 2 to 3 wt %, 2 to 2.9 wt %, 2.1 to 2.9 wt %, 2.1 to 2.8 wt %, 2.2 to 2.8 wt %, 2.2 to 2.7 wt % or 2.25 to 2.66 wt %.

In one embodiment, the alcohol amine compound may be a C₂₋₄ , alcohol amine compound.

In one embodiment, specific examples of the alcohol amine compound may include, but are not limited to: monoethanolamine (MEA), 2-methylarninoethanol (NMEA), N,N-dimethyl ethanol amine, diethanolamine, triethanolamine, iso-propanolamine, 2-amino-2-methyl-1-propanol and a combination thereof. The aforesaid alcohol amine compounds may be used alone or in combination of two or more.

In one embodiment, the content of the alcohol amine compound may be 20 to 95.5 wt %, for example, may be 20 to 92.5 wt %, 20 to 90 wt %, 20 to 87.5 wt %, 20 to 85 wt %, 20 to 82,5 wt %, 20 to 80 wt %, 20 to 77.5 wt %, 20 to 75 wt %, 20 to 72.5 wt %, 20 to 70 wt %, 20 to 67.5 wt %, 20 to 55 wt %, 20 to 62.5 wt %, 20 to 60 wt %, 20 to 57.5 wt %, 20 to 55 wt %, 20 to 52.5 wt %, 20 to 50 wt %, 22.5 to 50 wt %, 24.6 to 50 wt % or 24.6 to 49.2 wt %.

In one embodiment, specific examples of the amide compound may include, but are not limited to: formamide, ethanamide, carbamide, N-rnethylforrnamide (NMF), N-methylacetamide, N,N-diethylformamide, 1,3-dirnethylurea, N-(2-hydroxyethyl)-2-pyrrolidone, dimethylformamide (DMF), dimethylacetamide (DMAC) and a combination thereof. The aforesaid amide compounds may be used alone or in combination of two or more.

In one embodiment, the content of the amide compound may be 1 to 40 wt %, for example, 1 to 37.5 wt %, 1 to 35 wt %, 1 to 32.5 wt %, 1 to 30 wt %, 2 to 30 wt %, 2 to 27.5 wt %, 3 to 27.5 wt %, 3 to 25 wt %, 4 to 25 wt %, 5 to 25 wt %, 5 to 22.5 wt %, 5 to 20 wt %, 5 to 17.5 wt %, 5 to 15 wt %, 5 to 12.5 wt % or 5 to 10 wt %.

In one embodiment, the etching composition may further selectively comprise: a polar organic solvent, In one embodiment, the etching composition may further selectively comprise: a soluble polar organic solvent. Herein, the term “polar organic solvent” refers to an organic solvent with a dielectric constant greater than or equal to 15 measured at 1 KHz and 25° C. In addition, the term “soluble” polar organic solvent refers to that more than or equal to 0.1 g of the polar organic solvent can be dissolved in 100 ml of water at room temperature and normal pressure.

In one embodiment, the polar organic solvent may be selected from the group consisting of alcohol solvent, ketone solvent, ether solvent, furan solvent, sulfone solvent, ester solvent, alcohol ether solvent and a combination thereof.

In one embodiment, specific examples of the polar organic solvent may include, but are not limited to, ethylene glycol (EG), 1,2-propanediol, 1,3-propanediol (PG), glycerol, 1,4-butanediol (BOO), pentaerythritol (PENIA), 1,6-hexanediol (1,6-HDO), dipentaerythritol (DiPE), benzenediol, N-methylpyrrolidone (NMP), N-ethyl-2-pyrrolidone (NEP), propylene glycol methyl ether (PGME), butyl diglycol (BOG), tetrahydrofuran (THF), sulfolane (SFL), dimethyl sulfoxide (DM50), propylene glycol methyl ether acetate (PGMEA), γ-butyrolactone (GBL), ethylene carbonate (EC) and a combination thereof. The aforesaid polar organic solvent may be used alone or in combination of two or more.

In one embodiment, the content of the polar organic solvent may be 0 to 27,5 wt %.

When the content of the polar organic solvent is 0 wt %, it means that no polar organic solvent is intentionally added to the etching composition. When the polar organic solvent is added into the etching composition, the content of the polar organic solvent may be, for example, 0,1 to 27.5 wt %, 0.1 to 25 wt %, 0.1 to 22.5 wt %, 0.1 to 20 wt %, 1 to 20 wt %, 2 to 20 wt %, 3 to 20 wt %, 4 to 20 wt %, 5 to 20 wt %, 6 to 20 wt %, 7 to 20 wt %, 8 to 20 wt %, 9 to 20 wt % or 10 to 20 wt %.

In one embodiment, the etching composition may further selectively comprise: a non-polar organic solvent. In one embodiment, the etching composition may further selectively comprise: a soluble non-polar organic solvent. Herein, the term “non-polar organic solvent” refers to an organic solvent with a dielectric constant less than 15 measured at 1 KHz and 25′C. In addition, the term “soluble” non-polar organic solvent refers to that more than or equal to 0.1 g of the non-polar organic solvent can be dissolved in 100 ml of water at room temperature and normal pressure. The contact angle can be reduced or the wettability can be improved by adding an appropriate amount of the non-polar organic solvent. However, the use of the non-polar organic solvent is not necessary, and can be determined according to the requirements of the etching process (for example, the type or structure of the product to be etched).

In one embodiment, the non-polar organic solvent may be selected from the group consisting of alkane solvent, aromatic hydrocarbon solvent, long-chain alcohol solvent, alcohol ether solvent and a combination thereof.

In one embodiment, specific examples of the non-polar organic solvent may include, but are not limited to: benzene, toluene, ether, 1,4-dioxane, chloroform, butane, pentane, hexane, heptane, octane, nonane, decane, 1-pentanol, 1-hexanol, 1-heptanol, 1-octanol, 1-nonanol, n-decyl alcohol, undecanol, lauryl alcohol, isooctyl alcohol, diethylene glycol dimethyl ether, diethylene glycol diethyl ether (DEGDEE), diethylene glycol ethyl methyl ether, triethylene glycol dimethyl ether, tetraethylene glycol dimethyl ether, diethylene glycol monoethyl ether, diethylene glycol monohexyl ether and a combination thereof. The aforesaid non-polar organic solvent may be used alone or in combination of two or more.

In one embodiment, the content of the non-polar organic solvent may be 0 to 25 wt %. When the content of the non-polar organic solvent is 0 wt %, it means that no non-polar organic solvent is intentionally added to the etching composition. When the non-polar organic solvent is added into the etching composition, the content of the non-polar organic solvent may be, for example, 0.1 to 25 wt %, 1 to 25 wt %, 2 to 25 wt %, 3 to 25 wt %, 4 to 25 wt %, 5 to 25 wt %, 6 to 25 wt %, 7 to 25 wt %, 8 to 25 wt %, 9 to 25 wt % or 10 to 25 wt %, However, the present disclosure is not limited thereto. The amount of non-polar organic solvent added may also be more than 25 wt %, depending on the needs.

In one embodiment, the etching composition may further selectively comprise: a surfactant.

In one embodiment, the surfactant may be selected from the group consisting of:

fluorinated anionic surfactant, fluorinated nonionic surfactant, fluorinated amphoteric surfactant, hydrocarbon anionic surfactant and a combination thereof.

In one embodiment, specific examples of the surfactant may include, but are not limited to: Surfanol SE, Surfanol AD-01, Enoric-BS-24, Dynol 604, Dynol 607, FC-4430, FC-4434 and a combination thereof. The aforesaid surfactants may be used alone or in combination of two or more.

In one embodiment, the content of the surfactant may be 0 to 0.5 wt %. When the content of the surfactant is 0 wt %, it means that no surfactant is intentionally added to the etching composition. When the surfactant is added into the etching composition, the content of the surfactant may be, for example, 0.01 to 0.5 wt %, 0.01 to 0.4 wt %, 0.01 to 0.3 wt %, 0.01 to 0.2 wt %, 0.05 to 0.2 wt %, 0.05 to 0.15 wt %, 0.75 to 0.15 wt % or 0.75 to 1.25 wt %.

The present disclosure further provide a method for removing silicon by using the aforesaid etching composition, and the method comprises the following steps: providing a substrate to be etched, wherein the substrate to be etched comprises a silicon layer; and etching the substrate to be etched by using the aforesaid etching composition to remove at least a part of the silicon layer.

In one embodiment, the silicon layer may be an amorphous silicon layer, a monocrystalline silicon layer, a polycrystalline silicon layer or a combination thereof.

In one embodiment, the substrate to be etched may further comprise a silicon compound layer, and an etching selectivity of the silicon layer relative to the silicon compound layer may be greater than or equal to 7000, Herein, the silicon compound layer may be a silicon dioxide layer, a silicon nitride layer, a silicon carbide layer, a silicon carbide nitride layer or a combination thereof. In one embodiment, the silicon compound layer may be a silicon dioxide layer.

In one embodiment, the etching selectivity of the silicon layer relative to the silicon compound layer may be greater than or equal to 10000, greater than or equal to 20000, greater than or equal to 30000, greater than or equal to 40000, greater than or equal to 50000 or greater than or equal to 60000.

Herein, the etching selectivity of the silicon layer relative to the silicon compound layer can be calculated by the following equation (1):

Etching selectivity of the silicon layer relative to the silicon compound layer =Etching rate of the silicon layer/Etching rate of the silicon compound layer (1).

In one embodiment, the substrate to be etched may further comprise a work function material layer or a high-k material layer, and an etching selectivity of the silicon layer relative to the work function material layer or the high-k material layer may be greater than or equal to 1000. The work function material layer may be a titanium nitride layer, a tantalum nitride layer or a combination thereof. The high-k material layer may be a hafnium dioxide layer, a titanium dioxide layer, a zirconium dioxide layer or a combination thereof. In one embodiment., the work function material layer may be a titanium nitride layer.

in one embodiment, the etching selectivity of the silicon layer relative to the work function material layer or the high-k material layer may be greater than or equal to 3000, greater than or equal to 5000, greater than or equal to 7000, greater than or equal to 10000, greater than or equal to 15000, greater than or equal to 20000, greater than or equal to 25000, greater than or equal to 30000, greater than or equal to 35000, greater than or equal to 40000, greater than or equal to 45000, greater than or equal to 50000, greater than or equal to 55000 or greater than or equal to 60000.

Herein, the etching selectivity of the silicon layer relative to the high-k material layer can be calculated by the following equation (2), and the etching selectivity of the silicon layer relative to the work function material layer can be calculated by the following equation (3):

Etching selectivity of the silicon layer relative to the high-k material layer=Etching rate of the silicon layer/Etching rate of the high-k material layer (2); and

Etching selectivity of the silicon layer relative to the work function material layer=Etching rate of the silicon layer/Etching rate of the work function material layer (3).

In one embodiment, the etching composition may etch the substrate to be etched at 30 to 90° C., for examples, at 35 to 90° C., 40 to 90° C., 45 to 90° C., 50 to 90° C., 50 to 85° C., 55 to 85° C., 55 to 80° C., 60 to 75° C. or 65 to 75° C., but the present disclosure is not limited thereto. in the present disclosure, the temperature or time of etching may be adjusted according to the requirements of the process (for example, the structure of the substrate to be etched or the thickness of the silicon layer).

In the present disclosure, the etching rate may be calculated by the following equation (4):

Etching rate=(Thickness of the substrate to be etched before etching−Thickness of the substrate to be etched after etching)/Etching time (4).

In one embodiment, the method of the present disclosure may be used in a process for manufacturing a high-k metal gate transistor. More specifically, the method of the present disclosure may be used in a process for manufacturing a high-k metal gate transistor to remove the silicon layer which acts as a dummy gate.

In the present disclosure, the term “alkyl” refers to a straight or branched hydrocarbon group comprising 1-12 carbon atoms (e.g., C₁-C₁₀, C₁-C₈ OR C₁-C₅). Examples of the alkyl may include methyl, ethyl, n-propyl, isopropyl, n-butyl, isobutyl and tert-butyl.

In the present disclosure, the term “aryl” refers to 6-carbon monocyclic, 10-carbon bicyclic and 14-carbon tricyclic aromatic ring systems. Examples of the aryl include phenyl, naphthyl and anthracenyl.

In addition, unless otherwise specified, the alkyl or aryl in the compound includes substituted or unsubstituted groups. Possible substituents include, but are not limited to, alkyl, cycloalkyl, halogen, alkoxyl, alkenyl, heterocycloalkyl, aryl, heteroaryl, amino group, carboxyl or hydroxyl, but alkyl is not substituted by alkyl.

Other novel features of the disclosure will become more apparent from the following detailed description when taken in conjunction with the accompanying drawings.

### BRIEF DESCRIPTION OF DRAWINGS

FIG. 1A to FIG. 1D are cross-sectional views showing the process for manufacturing a high-k metal gate transistor according to one embodiment of the present disclosure.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

In the present specification, except otherwise specified, the feature A “or” the feature B means the existence of the feature A or the existence of the feature B. The feature A “and/or” the feature B means the existence of the feature A, the existence of the feature B, or the existence of both the features A and B. The feature A “and” the feature B means the existence of both the features A and B. The term “comprise(s)”, “comprising”, “include(s)”, “including”, “have”, “has” and “having” means “comprise(s)/comprising but is/are/being not limited to”.

In the present disclosure, except otherwise specified, the terms “almost”, “about” and “approximately” usually mean the acceptable error in the specified value determined by a skilled person in the art, and the error depends on how the value is measured or determined. In some embodiments, the terms “almost”, “about” and “approximately” mean within 1, 2, 3 or 4 standard deviations. In some embodiments, the terms “almost”, “about” and “approximately” mean within ±20%, within ±15%, within ±10%, within ±9%, within ±8%, within ±7%, within ±6%, within ±5%, within ±4%, within ±3%, within ±2%, within ±1%, within ±0.5%, within ±0.05% or less of a given value or range. The quantity given here is an approximate quantity, that is, without specifying “almost”, “about” and “approximately”, it can still imply “almost”, “about” and “approximately”. In addition, the terms “in a range of a first value to a second value”, “from a first value to a second value” and the like mean the said range comprises the first value, the second value and other values between the first value and the second value.

In addition, the features in different embodiments of the present disclosure can be mixed to form another embodiment.

In the following Examples (abbreviated as Ex) and Comparative examples (abbreviated as Comp Ex), the target substrate (a polysilicon substrate with a thickness of 5000 Å, a silicon dioxide (SiO₂) substrate with a thickness of 1000 Å, and a titanium nitride (TiN) substrate with a thickness of 100 Å) was immersed in the heated etching composition, stirred by a magnet, and etched for a predetermined time. Herein, the components and contents of the etching compositions of Examples and Comparative examples are shown in Tables 1 to 10 below. The polysilicon substrate was immersed in the etching composition heated to 70° C. for 1 or 2 minutes; and the silicon dioxide substrate and the titanium nitride substrate were immersed in the etching composition heated to 70° C. for 120 minutes.

The thicknesses of the target substrate before and after etching were measured, and the etching rates were calculated with the above equation (4). In addition, the etching selectivity of the polysilicon substrate (i.e., the silicon layer) relative to the silicon dioxide substrate (i.e., the silicon compound layer) was calculated by the above equation (1), and, the etching selectivity of the polysilicon substrate (i.e., the silicon layer) relative to the titanium nitride substrate (i.e., the work function material layer) was calculated by the above equation (3). The calculation results are listed in Tables 1. to 10 below.

Measurement of contact angle

The measurement of the contact angle was briefly described. The etching compositions of Examples and Comparative examples (3 μL droplets) were applied on the surface of the target substrate (Poly-Si, SiO₂). Start timing for 10 s, and measure with a contact angle meter (Theta T200-basic). The experiments were performed in triplicate. The average value of the contact angles was obtained by software statistics (Attension).

### TEXT EXAMPLE 1

The components and contents of the etching compositions, etching rates and etching selectivity are listed in the following Table 1.

TABLE 1

| | Comp Ex 1-1 | Ex 1-1 | Ex 1-2 | Ex 1-3 | Ex 1-4 | Comp Ex 1-2 |
|---|---|---|---|---|---|---|
| | Component | Component | Component | Component | Component | Component |
| | wt % | wt % | wt % | wt % | wt % | wt % |
| Quaternary | TMAH | TMAH | TMAH | TMAH | TMAH | TMAH |
| ammonium salt | 0.5 | 1 | 2.5 | 4 | 5.5 | 6.5 |
| Surfactant | FC-4434 | FC-4434 | FC-4434 | — | FC-4434 | FC-4434 |
| | 0.10 | 0.10 | 0.10 | | 0.10 | 0.10 |
| Water | 55.4 | 54.9 | 53.4 | 21.4 | 50.4 | 49.4 |
| Alcohol amine | NMEA | NMEA | NMEA | NMEA | NMEA | NMEA |
| compound | 20 | 20 | 20 | 24.6 | 20 | 20 |
| Polar organic solvent | EG | EG | EG | EG | EG | EG |
| | 20 | 20 | 20 | 15 | 20 | 20 |
| Amide compound | NMF | NMF | NMF | NMF | NMF | NMF |
| | 4 | 4 | 4 | 25 | 4 | 4 |
| Non-polar organic | — | — | — | 1-Hexanol | — | — |
| solvent | | | | 10 | | |
| Poly-Si etching rate | 1458 | 1400 | 1817 | 980 | 1873 | 2885 |
| (Å/min) | | | | | | |
| SiO₂ etching rate | 0.51 | 0.2 | 0.195 | 0.071 | 0.18 | 0.6 |
| (Å/min) | | | | | | |
| Poly-Si/SiO₂ | 2858 | 7000 | 9317 | 13802 | 10405 | 4808 |
| selectivity | | | | | | |
| TiN etching rate | — | — | — | 0.007 | — | — |
| (Å/min) | | | | | | |
| Poly-Si/TiN | — | — | — | 140000 | — | — |
| selectivity | | | | | | |

As shown in Table 1, compared with the etching compositions of Comparative examples 1-1 and 1-2, the silicon dioxide etching rates of the etching compositions of Examples 1-1 to 1-4 are all less than 0.2 Å/min, and the etching selectivity of polysilicon relative to silicon dioxide is greater than 7000. These results indicate that the content of the quaternary ammonium salt in the etching composition is preferably in a range from 1 to 5.5 wt %. In addition, the etching composition of Example 1-3 also has low etching rate of titanium nitride and excellent etching selectivity of polysilicon relative to titanium nitride.

### TEXT EXAMPLE 2

The components and contents of the etching compositions, etching rates and etching selectivity are listed in the following Table 2.

TABLE 2

| | Comp Ex 2-1 | Ex 2-1 | Ex 2-2 | Ex 2-3 | Ex 2-4 | Comp Ex 2-2 |
|---|---|---|---|---|---|---|
| | Component | Component | Component | Component | Component | Component |
| | wt % | wt % | wt % | wt % | wt % | wt % |
| Quaternary | TMAH | TMAH | TMAH | TMAH | TMAH | TMAH |
| ammonium salt | 2.25 | 2.25 | 2.25 | 2.25 | 2.25 | 2.25 |
| Surfactant | FC-4434 | FC-4434 | FC-4434 | FC-4434 | FC-4434 | FC-4434 |
| | 0.10 | 0.10 | 0.10 | 0.10 | 0.10 | 0.10 |
| Water | 46.9 | 46.65 | 38.05 | 28.05 | 18.05 | 15.55 |
| Alcohol amine | NMEA | NMEA | NMEA | NMEA | NMEA | NMEA |
| compound | 40 | 40 | 24.6 | 24.6 | 24.6 | 24.6 |
| Polar organic solvent | EG | EG | EG | EG | EG | EG |
| | 10 | 10 | 15 | 15 | 15 | 15 |
| Amide compound | NMF | NMF | NMF | NMF | NMF | NMF |
| | 0.75 | 1 | 20 | 30 | 40 | 42.5 |
| Poly-Si etching rate | 2160 | 2100 | 1836 | 1512 | 1394 | 342 |
| (Å/min) | | | | | | |
| SiO₂ etching rate | 0.59 | 0.26 | 0.22 | 0.09 | 0.13 | 0.103 |
| (Å/min) | | | | | | |
| Poly-Si/SiO₂ | 3661 | 8076 | 8345 | 16800 | 10723 | 3320 |
| selectivity | | | | | | |

As shown in Table 2, compared with the etching compositions of Comparative Examples 2-1 and 2-2, the silicon dioxide etching rates of the etching compositions of Examples 2-1 to 2-4 are all less than 0.3 Å/min, and the etching selectivity of polysilicon relative to silicon dioxide is greater than 7000. These results indicate that the content of the amide compound in the etching composition is preferably in a range from 1 to 40 wt %.

### TEXT EXAMPLE 3

The components and contents of the etching compositions, etching rates and etching selectivity are listed in the following Table 3.

TABLE 3

| | Comp Ex 3-1 | Ex 3-1 | Ex 3-2 | Ex 3-3 | Ex 3-4 | Comp Ex 3-2 |
|---|---|---|---|---|---|---|
| | Component | Component | Component | Component | Component | Component |
| | wt % | wt % | wt | wt % | wt % | wt % |
| Quaternary | TMAH | TMAH | TMAH | Choline | Choline | Choline |
| ammonium salt | 2.25 | 2.25 | 2.25 | hydroxide | hydroxide | hydroxide |
| | | | | 2.66 | 1 | 1 |
| Surfactant | FC-4434 | FC-4434 | FC-4434 | FC-4434 | FC-4434 | FC-4434 |
| | 0.10 | 0.10 | 0.10 | 0.50 | 0.10 | 0.10 |
| Water | 53.65 | 52.65 | 23.45 | 15.84 | 1.9 | 1.9 |
| Alcohol amine | MEA | MEA | NMEA | MEA | NMEA | MEA |
| compound | 19 | 20 | 49.2 | 70 | 95.5 | 97 |
| Polar organic solvent | EG | EG | EG | EG | EG | — |
| | 15 | 15 | 15 | 10 | 0.5 | |
| Amide compound | NMF | NMF | NMF | NMF | NMF | — |
| | 10 | 10 | 10 | 1 | 1 | |
| Poly-Si etching rate | 1697 | 2250 | 1471 | 2306 | 1133 | 590 |
| (Å/min) | | | | | | |
| SiO₂ etching rate | 0.28 | 0.11 | 0.054 | 0.19 | 0.023 | 0.11 |
| (Å/min) | | | | | | |
| Poly-Si/SiO₂ | 6060 | 23181 | 27240 | 12136 | 49260 | 5363 |
| selectivity | | | | | | |
| TiN etching rate | — | — | — | 0.073 | 0.02 | — |
| (Å/min) | | | | | | |
| Poly-Si/TiN | — | — | — | 31589 | 56650 | — |
| selectivity | | | | | | |

As shown in Table 3, compared with the etching compositions of Comparative examples 3-1 and 3-2, the silicon dioxide etching rates of the etching compositions of Examples 3-1 to 3-4 are all less than 0.2 Å/min, and the etching selectivity of polysilicon relative to silicon dioxide is greater than 7000. These results indicate that the content of the alcohol amine compound in the etching composition is preferably in a range from 20 to 95.5 wt %. In addition, the etching compositions of Examples 3-3 and 3-4 also have low etching rate of titanium nitride and excellent etching selectivity of polysilicon relative to titanium nitride.

### TEXT EXAMPLE 4

The components and contents of the etching compositions, etching rates and etching selectivity are listed in the following Table 4.

TABLE 4

| | Ex 4-1 | Ex 4-2 |
|---|---|---|
| | Component | Component |
| | wt % | wt % |
| Quaternary ammonium salt | TMAH | Choline hydroxide |
| | 2.25 | 2.66 |
| Surfactant | FC-4434 | FC-4434 |
| | 0.1 | 0.1 |
| Water | 53.65 | 47.64 |
| Alcohol amine compound | NMEA | NMEA |
| | 20 | 24.6 |
| Polar organic solvent | EG | EG |
| | 20 | 15 |
| Amide compound | NMF | NMF |
| | 4 | 10 |
| Poly-Si etching rate (Å/min) | 1817 | 2599 |
| SiO₂ etching rate (Å/min) | 0.195 | 0.098 |
| Poly-Si/SiO₂ selectivity | 9317 | 26520 |

As shown in Table 4, even though the quaternary ammonium salt different from TMAH is used (such as choline hydroxide), high polysilicon etching rate and low silicon dioxide etching rate can be achieved, and excellent etching selectivity of polysilicon relative to silicon dioxide can also be exhibited.

### TEXT EXAMPLE 5

The components and contents of the etching compositions, etching rates and etching selectivity are listed in the following Table 5.

TABLE 5

| | Ex 5-1 | Ex 5-2 | Ex 5-3 | Ex 5-4 |
|---|---|---|---|---|
| | Component | Component | Component | Component |
| | wt % | wt % | wt % | wt % |
| Quaternary ammonium salt | TMAH | TMAH | Choline hydroxide | TMAH |
| | 2.25 | 2.25 | 2.66 | 2.2.5 |
| Surfactant | FC-4434 | FC-4434 | FC-4434 | FC-4434 |
| | 0.10 | 0.10 | 0.10 | 0.10 |
| Water | 48.05 | 53.05 | 47.64 | 53.05 |
| Alcohol amine compound | NMEA | NMEA | NMEA | NMEA |
| | 24.6 | 24.6 | 24.6 | 24.6 |
| Polar organic solvent | EG | EG | EG | EG |
| | 15 | 10 | 15 | 10 |
| Amide compound | Ethanamide | Ethanamide | Ethanamide | N,N- |
| | 10 | 10 | 10 | diethylformamide |
| | | | | 10 |
| Poly-Si etching rate (Å/min) | 3302 | 2262 | 2599 | 2069 |
| SiO₂ etching rate (Å/min) | 0.079 | 0.13 | 0.098 | 0.29 |
| Poly-Si/SiO₂ selectivity | 41797 | 17400 | 26520 | 7134 |

As shown in Table 5, even though the amide compound different from NMF is used (such as ethanamide or N,N-diethylformamide), high polysilicon etching rate and low silicon dioxide etching rate can be achieved, and excellent etching selectivity of polysilicon relative to silicon dioxide can also be exhibited.

### TEXT EXAMPLE 6

The components and contents of the etching compositions, etching rates and etching selectivity are listed in the following Table 6.

TABLE 6

| | Ex 6-1 | Ex 6-2 | Ex 6-3 |
|---|---|---|---|
| | Component | Component | Component |
| | wt % | wt % | wt % |
| Quaternary ammonium salt | TMAH | TMAH | TMAH |
| | 2.25 | 2.25 | 2.25 |
| Surfactant | FC-4434 | FC-4434 | FC-4434 |
| | 0.1 | 0.1 | 0.1 |
| Water | 52.65 | 23.45 | 48.45 |
| Alcohol amine compound | MEA | NMEA | 2-amino- |
| | 20 | 49.2 | 2-methyl- |
| | | | 1-propanol |
| | | | 29.2 |
| Polar organic solvent | EG | EG | EG |
| | 15 | 15 | 10 |
| Amide compound | NMF | NMF | NMF |
| | 10 | 10 | 10 |
| Poly-Si etching rate (Å/min) | 2250 | 1471 | 1473 |
| SiO₂ etching rate (Å/min) | 0.11 | 0.054 | 0.025 |
| Poly-Si/SiO₂ selectivity | 23181 | 27240 | 58920 |

As shown in Table 5, even though the alcohol amine compound different from NMEA is used (such as MEA or 2-arnino-2-methyl-1-propanol), high polysilicon etching rate and low silicon dioxide etching rate can be achieved, and excellent etching selectivity of polysilicon relative to silicon dioxide can also be exhibited.

### TEST EXAMPLE 7

The components and contents of the etching compositions, etching rates and etching selectivity are listed in the following Table 7.

TABLE 7

| | Ex 7-1 | Ex 7-2 | Ex 7-3 | Ex 7-4 | Ex 7-5 | Comp Ex 7-1 |
|---|---|---|---|---|---|---|
| | Component | Component | Component | Component | Component | Component |
| | wt % | wt % | wt % | wt % | wt % | wt % |
| Quaternary | TMAH | TMAH | TMAH | TMAH | TMAH | TMAH |
| ammonium salt | 2.25 | 2.25 | 2.25 | 2.25 | 2.25 | 2.25 |
| Surfactant | FC-4434 | FC-4434 | FC-4434 | FC-4434 | FC-4434 | FC-4434 |
| | 0.10 | 0.10 | 0.10 | 0.10 | 0.10 | 0.10 |
| Water | 47.65 | 37.65 | 53.65 | 48.65 | 46.15 | 44.65 |
| Alcohol amine | NMEA | NMEA | NMEA | NMEA | NMEA | NMEA |
| compound | 40 | 40 | 20 | 20 | 20 | 20 |
| Polar organic solvent | — | EG | EG | EG | EG | EG |
| | | 10 | 20 | 25 | 27.5 | 29 |
| Amide compound | NMF | NMF | NMF | NMF | NMF | NMF |
| | 10 | 10 | 4 | 4 | 4 | 4 |
| Poly-Si etching rate | 1794 | 1535 | 1817 | 1749 | 1624 | 1938 |
| (Å/min) | | | | | | |
| SiO₂ etching rate | 0.08 | 0.066 | 0.195 | 0.248 | 0.108 | 0.31 |
| (Å/min) | | | | | | |
| Poly-Si/SiO₂ | 22425 | 2.3275 | 9317 | 7052 | 15037 | 6251 |
| selectivity | | | | | | |

As shown in Table 7, compared with the etching composition of Comparative example 7-1, the silicon dioxide etching rates of the etching compositions of Examples 7-1 to 7-5 are all less than 0.25 Amin, and the etching selectivity of polysilicon relative to silicon dioxide is greater than 7000. These results indicate that the content of the polar organic solvent in the etching composition is preferably in a range from 0 to 27.5 wt %.

### TEST EXAMPLE 8

The components and contents of the etching compositions, etching rates and etching selectivity are listed in the following Table 8.

TABLE 8

| | Ex 8-1 | Ex 8-2 | Ex 8-3 |
|---|---|---|---|
| | Component | Component | Component |
| | wt % | wt % | wt % |
| Quaternary ammonium salt | TMAH | TMAH | TMAH |
| | 2.25 | 2.25 | 2.25 |
| Surfactant | FC-4434 | FC-4434 | FC-4434 |
| | 0.2 | 0.1 | 0.1 |
| Water | 47.95 | 38.05 | 23.05 |
| Alcohol amine compound | NMEA | NMEA | NMEA |
| | 24.6 | 24.6 | 24.6 |
| Polar organic solvent | EG | EG | EG |
| | 15 | 15 | 15 |
| Non-polar organic solvent | — | 1-Hexanol | 1-Hexanol |
| | | 10 | 25 |
| Amide compound | NMF | NMF | NMF |
| | 10 | 10 | 10 |
| Poly-Si etching rate (Å/min) | 2187 | 1665 | 2446 |
| SiO₂ etching rate (Å/min) | 0.13 | 0.03 | 0.19 |
| Poly-Si/SiO₂ selectivity | 16823 | 55500 | 12873 |
| TiN etching rate (Å/min) | — | — | 0.03 |
| Poly-Si/TiN selectivity | — | — | 81533 |
| Poly-Si contact angle | 17.45 | <3 | 10.3 |
| (degree) | | | |
| SiO₂ contact angle (degree) | 14.81 | <3 | 10.5 |

As shown in Table 8, whether the non-polar organic solvent is added or not, high polysilicon etching rate and low silicon dioxide etching rate can be achieved, and excellent etching selectivity of polysilicon relative to silicon dioxide can also be exhibited. In addition, compared with the etching composition of Example 8-1 without adding the non-polar organic solvent, the etching compositions of Examples 8-2 and 8-3 with adding the non-polar organic solvent can reduce the contact angle, improve the permeability and wettability of the etching composition, and thus be applicable to fine semiconductor structure,

### TEST EXAMPLE 9

The components and contents of the etching compositions, etching rates and etching selectivity are listed in the following Table 9.

TABLE 9

| | Comp Ex 9-1 | Comp Ex 9-2 | Comp Ex 9-3 |
|---|---|---|---|
| | Component | Component | Component |
| | wt % | wt % | wt % |
| Quaternary ammonium salt | TMAH | TMAH | TMAH |
| | 2.2.5 | 2.25 | 2.25 |
| Surfactant | FC-4434 | FC-4434 | FC-4434 |
| | 0.10 | 0.10 | 0.10 |
| Water | 53.05 | 43.05 | 45.75 |
| Alcohol amine compound | NMEA | NMEA | NMEA |
| | 24.6 | 24.6 | 36.9 |
| Polar organic solvent | EG | EG | EG |
| | 10 | 20 | 10 |
| Nitrogen-containing compound | 1-Methylimidazole | 1-Methylimidazole | 1-Methylimidazole |
| | 10 | 10 | 5 |
| Poly-Si etching rate (Å/min) | 1919 | 1656 | 1975 |
| SiO₂ etching rate (Å/min) | 0.51 | 0.48 | 0.44 |
| Poly-Si/SiO₂ selectivity | 3762 | 3450 | 4488 |

As shown in Table 9, when the amide compound in the etching composition is replaced by other nitrogen-containing compound (such as 1-methylimidazole), desired silicon dioxide etching rate and etching selectivity of polysilicon relative to silicon dioxide cannot be achieved.

### TEST EXAMPLE 10

The components and contents of the etching compositions, etching rates and etching selectivity are listed in the following Table 10.

TABLE 10

| | Ex 10-1 | Ex 10-2 | Ex 10-3 |
|---|---|---|---|
| | Component | Component | Component |
| | wt % | wt % | wt % |
| Quaternary ammonium salt | TMAH | TMAH | TMAH |
| | 2.25 | 2.25 | 2.25 |
| Surfactant | FC-4434 | FC-4434 | FC-4434 |
| | 0.1 | 0.1 | 0.1 |
| Water | 28.45 | 28.45 | 18.45 |
| Alcohol amine compound | NMEA | NMEA | NMEA |
| | 49.2 | 49.2 | 49.2 |
| Polar organic solvent | EG | EG | EG |
| | 15 | 10 | 20 |
| Amide compound | NMF | NMF | NMF |
| | 5 | 10 | 10 |
| Poly-Si etching rate (Å/min) | 1501 | 1736 | 1979 |
| SiO₂ etching rate (Å/min) | 0.025 | 0.014 | 0.0021 |
| Poly-Si/SiO₂ selectivity | 60040 | 124000 | 942380 |

As shown in Table 10, in the etching composition, when the content of the quaternary ammonium salt is about 2.25 wt %, the content of the surfactant is about 0.1 wt %, the content of the alcohol amine compound is about 49.2 wt %, the content of the polar organic solvent is about 10 to 20 wt % and the content of the amide compound is about 5 to 10 wt %, the etching selectivity of polysilicon relative to silicon dioxide can be greater than 60000.

The results shown in Table 1 to Table 10 indicate that the etching composition of the present disclosure can exhibit excellent etching selectivity of polysilicon relative to silicon dioxide, and also excellent etching selectivity of polysilicon relative to titanium nitride. Thus, the etching composition of the present disclosure can be applied to the manufacture of electronic products or semiconductor devices. For example, the etching composition of the present disclosure can be applied to the manufacture of the high-k metal gate transistor.

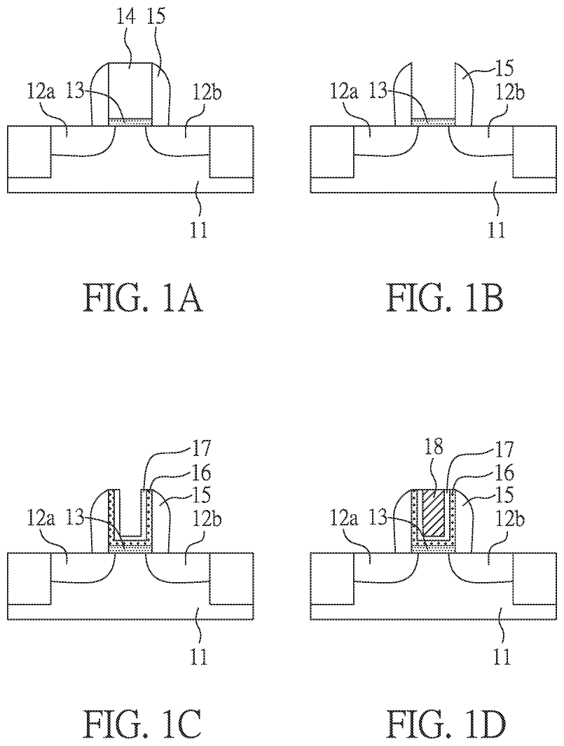

FIG. 1A to FIG. 1D are cross-sectional views showing the process for manufacturing a high-k metal gate transistor according to one embodiment of the present disclosure.

As shown in FIG. 1A, a conventional transistor is firstly provided, which comprises: a p-type silicon layer 11; n-type silicon layers 12a, 12b as a source and a drain respectively; a spacer 15 disposed on the p-type silicon layer 11, wherein the material of the spacer 15 is a silicon compound such as silicon nitride or silicon carbide nitride; a gate insulating layer 13 disposed on the p-type silicon layer 11 and between the n-type silicon layers 12a, 12b, wherein the material of the gate insulating layer 13 is a silicon compound such as silicon dioxide; and a dummy gate 14 disposed on the gate insulating layer 13, wherein the material of the dummy gate 14 is polysilicon.

As shown in FIG. 1B, the dummy gate 14 is removed by using the etching composition of the present disclosure. Since the material of the dummy gate 14 is polysilicon and the etching composition of the present disclosure has excellent etching selectivity of polysilicon relative to the silicon compound, the polysilicon of the dummy gate 14 can be effectively removed and the silicon compound of the gate insulating layer 13 and the spacer 15 (such as silicon nitride, silicon carbide nitride or silicon dioxide) can be retained.

As shown in FIG. 1C, a high-k material (such as 140₂,110₂, ZrO₂ or others) is deposited in the hole of the spacer 15 to form a high-k material layer 16. Then, a work function material layer 17 is formed on the high-k material layer 16. The material of the work function material layer 17 include titanium nitride (TiN), tantalum nitride (TaN), ruthenium (Ru), molybdenum (Mo), etc., but the present disclosure is not limited thereto. As shown in FIG. 1D, a metal gate 18 is formed on the work function material layer 17, and the material of the metal gate 18 may be Ti, Al, other suitable metal or metal alloy. After the aforesaid process, a high-k metal gate transistor is obtained.

Although the present disclosure has been explained in relation to its embodiment, it is to be understood that many other possible modifications and variations can be made without departing from the spirit and scope of the disclosure as hereinafter claimed

1. An etching composition for removing silicon, comprising:
1 to 5,5 wt % of a quaternary ammonium salt;
20 to 95.5 wt % of an alcohol amine compound;
1 to 40 wt % of an amide compound; and
rest of water.

2. The etching composition of claim 1, wherein the quaternary ammonium salt is represented by the following formula (I):
N(R¹)₄⁺X⁻ (I)
wherein each R¹ independently is substituted or unsubstituted alkyl, or substituted or unsubstituted aryl;
X⁻ is F⁻, Cl⁻, I⁻, HSO₄⁻, R²COO⁻or OH⁻; and
R² is H or substituted or unsubstituted alkyl.

3. The etching composition of claim 2, wherein each R¹ independently is substituted or unsubstituted C₁₋₅ alkyl, or substituted or unsubstituted C₆₋₁₀ aryl.

4. The etching composition of claim 1, wherein the quaternary ammonium salt is selected from the group consisting of tetrarnethyl ammonium hydroxide (TMAH), tetraethylarnmoniurn hydroxide (TEAH), tetrapropylammonium hydroxide (TPNH), tetrabutylammonium hydroxide (TBAH), benzyltrimethylammonium hydroxide, triethylmethylammonium hydroxide, choline hydroxide and a combination thereof.

5. The etching composition of claim 1, wherein the alcohol amine compound is a C₂₋₄ alcohol amine compound.

6. The etching composition of claim 1, wherein the alcohol amine compound is selected from the group consisting of monoethanolamine (MEA), 2-methylaminoethanol (NIMEA), N,N-dimethyl ethanol amine, diethanolamine, triethanolamine, iso-propanolarnine, 2-amino-2-methyl-1-propanol and a combination thereof.

7. The etching composition of claim 1, wherein the amide compound is selected from the group consisting of formamide, ethanamide, carbamide, N-methylformamide (NMF), N-methylacetamide, N,N-diethylformamide, 1,3-dirnethylurea, N-(2-hydroxyethyl)-2-pyrrolidone, dimethylformamide (DMF), dimethylacetamide (DMAC) and a combination thereof.

8. The etching composition of claim 1, further comprising: 0 to 27.5 wt % of a polar organic solvent.

9. The etching composition of claim 8, wherein the polar organic solvent is selected from the group consisting of alcohol solvent, ketone solvent, ether solvent, furan solvent, sulfone solvent, ester solvent, alcohol ether solvent and a combination thereof.

10. The etching composition of claim 8, wherein the polar organic solvent is selected from the group consisting of ethylene glycol (EG), 1,2-propanediol, 1,3-propanediol (PG), glycerol, 1,4-butanediol (BDO), pentaerythritol (PENTA), 1,6-hexanediol (1,6-HDO), dipentaerythritol (DiPE), benzenediol, N-methylpyrrolidone (NMP), N-ethyl-2-pyrrolidone (NEP), propylene glycol methyl ether (PGME), butyl diglycol (BDG), tetrahydrofuran (THF), sulfolane (SFL), dimethyl sulfoxide (DMSO), propylene glycol methyl ether acetate (PGMEA), γ-butyrolactone (GBL), ethylene carbonate (EC) and a combination thereof.

11. The etching composition of claim 1, further comprising: a non-polar organic solvent.

12. The etching composition of claim 11, wherein the non-polar organic solvent is selected from the group consisting of alkane solvent, aromatic hydrocarbon solvent, long-chain alcohol solvent, alcohol ether solvent and a combination thereof.

13. The etching composition of claim 11, wherein the non-polar organic solvent is selected from the group consisting of benzene, toluene, ether, 1,4-dioxane, chloroform, butane, pentane, hexane, heptane, octane, nonane, decane, 1-pentanol, 1-hexanol, 1-heptanol, 1-octanol, 1-nonanol, n-decyl alcohol, undecanol, lauryl alcohol, isooctyl alcohol, diethylene glycol dimethyl ether, diethylene glycol diethyl ether (DEGDEE), diethylene glycol ethyl methyl ether, triethylene glycol dimethyl ether, tetraethylene glycol dimethyl ether, diethylene glycol monoethyl ether, diethylene glycol monohexyl ether and a combination thereof.

14. The etching composition of claim 1, further comprising: 0 to 0.5 wt % of a surfactant.

15. The etching composition of claim 14, wherein the surfactant is selected from the group consisting of: fluorinated anionic surfactant, fluorinated nonionic surfactant, fluorinated amphoteric surfactant, hydrocarbon anionic surfactant and a combination thereof.

16. The etching composition of claim 1, wherein the silicon is amorphous silicon, monocrystalline silicon, polycrystalline silicon or a combination thereof.

17. A method for removing silicon, comprising the following steps:
providing a substrate to be etched, wherein the substrate to be etched comprises a silicon layer;
and etching the substrate to be etched by using the etching composition of claim 1 to remove at least a part of the silicon layer.

18. The method of claim 17, wherein the substrate to be etched further comprises a silicon compound layer, and an etching selectivity of the silicon layer relative to the silicon compound layer is greater than or equal to 7000.

19. The method of claim 17, wherein the substrate to be etched further comprises a work function material layer or a high-k material layer, and an etching selectivity of the silicon layer relative to the work function material layer or the high-k material layer is greater than or equal to 1000.

20. The method of claim 17, wherein the method is used in a process for manufacturing a high-k metal gate transistor, wherein the silicon layer is a dummy gate.
